(19) United States
(12) Patent Application Publication
(10) Pub. No.: US 2017/0302229 A1
(43) Pub. Date: Oct. 19, 2017

(54) AMPLIFICATION DEVICE

(71) Applicant: FUJITSU LIMITED, Kawasaki-shi (JP)

(72) Inventors: Takumi Takayashiki, Sendai (JP); Tatsuhiko Tajima, Tagajo (JP); Daisuke Masunaga, Sendai (JP)

(73) Assignee: FUJITSU LIMITED, Kawasaki-shi (JP)

(21) Appl. No.: 15/463,811

(22) Filed: Mar. 20, 2017

(30) Foreign Application Priority Data
Apr. 14, 2016 (JP) 2016-081298

(51) Int. Cl. H03F 1/30; H03F 3/21; H03F 1/02; H03F 3/19

(52) U.S. Cl. CPC H03F 1/30; H03F 3/19; H03F 3/211; H03F 1/0288; H03F 2200/18; H03F 2200/451; H03F 2200/468; H03F 2203/21161; H03F 2200/321

(57) ABSTRACT

An amplification device includes a first amplifier configured to amplify an input signal in accordance with a first gate voltage, and a second amplifier configured to amplify the input signal in accordance with a second gate voltage, wherein at least one of the first gate voltage and the second gate voltage are controlled on the basis of a current ratio of a first drain current of the first amplifier to a second drain current of the second amplifier.

### CROSS-REFERENCE TO RELATED APPLICATION

This application is based upon and claims the benefit of priority of the prior Japanese Patent Application No. 2016-081298, filed on Apr. 14, 2016, the entire contents of which are incorporated herein by reference.

### FIELD

The embodiments discussed herein are related to an amplification device.

### BACKGROUND

Amplification circuits, which amplify transmission power, have been used in various radio apparatuses including a base station of a mobile communication system. Particularly, in recent years, along with high-speed communication, it is desired to amplify the transmission power with higher efficiency from a viewpoint of reducing the power consumption. It is known that the efficiency of an amplification circuit is the highest in an output saturation state (nonlinear state), and as an amplification circuit having this characteristic, a Doherty amplification circuit (hereinafter referred to as a “Doherty circuit”) may be used. A Doherty circuit has a carrier amplifier (CA) and a peak amplifier (PA) which are coupled in parallel, and a gate voltage applied to the CA and PA is normally fixed to an optimal operation point at which the efficiency has a maximum.

However, it is known that the optimal operation point varies with change in temperature. When the gate voltage deviates from the optimal operation point due to a change in temperature, the input/output characteristics of the Doherty circuit changes. Consequently, a signal outputted from the Doherty circuit is distorted.

In order to reduce such a deviation of the gate voltage, a technology in related art controls the gate voltage applied to the CA and PA using, for instance, a temperature variable resistor. Also, a technology in related art detects a drain current of the CA and PA which varies according to a change in temperature, and controls the gate voltage so that the detected drain current falls within a predetermined range.

Related techniques are disclosed in, for example, Japanese Laid-open Patent Publication Nos. 2006-279707 and 2007-129492.

### SUMMARY

According to an aspect of the invention, an amplification device includes a first amplifier configured to amplify an input signal in accordance with a first gate voltage, and a second amplifier configured to amplify the input signal in accordance with a second gate voltage, wherein at least one of the first gate voltage and the second gate voltage are controlled on the basis of a current ratio of a first drain current of the first amplifier to a second drain current of the second amplifier.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating an example base station including a radio apparatus in a first embodiment;

FIG. 2 is a block diagram illustrating an example amplification device in the first embodiment;

FIG. 3 is a graph illustrating an example relationship between current ratio and distortion of output signal due to change in temperature;

FIG. 4 is a flowchart illustrating example gate voltage control processing in the first embodiment;

FIG. 5 is a flowchart illustrating another example gate voltage control processing in the first embodiment;

FIG. 6 is a block diagram illustrating an example amplification device in a second embodiment;

FIG. 7 is a table illustrating an example conversion table in which a range of temperature difference and a current difference are associated with each other; and

FIG. 8 is a flowchart illustrating example gate voltage control processing in the second embodiment.

### DESCRIPTION OF EMBODIMENTS

A deviation of the gate voltage is caused not only by a change in temperature, but also by a mechanical error (hereinafter referred to as an “individual difference of parts”) in the CA and PA. Specifically, the optimal operation point of the CA and PA, and the amount of change in the drain current vary with the CA and PA, and the amount of deviation of the gate voltage also varies according to the variation.

However, in the above-mentioned technology in related art, reduction of deviation of the gate voltage caused by the individual difference of parts is not taken into consideration.

Specifically, in a technology in related art which controls the gate voltage using a temperature variable resistor, an uniform gate voltage is applied at a certain temperature, and thus when the optimal operation point varies due to the individual difference of parts, deviation of the gate voltage still occurs. Also, in a technology in related art which controls the gate voltage so that the drain current falls within a predetermined range, when the amount of change in the drain current varies due to the individual difference of parts, the accuracy of control of the gate voltage is reduced, and thus deviation of the gate voltage occurs.

Like this, in the technologies in related art, the optimal operation point and the amount of change in the drain current vary due to the individual difference of parts, and thus deviation of the gate voltage occurs. As a result, the signal outputted from the Doherty circuit is distorted.

The technology of the present disclosure has been made in view of the above-mentioned problems, and provides an amplification device and a radio apparatus that are capable of reducing an occurrence of distortion in the Doherty circuit.

Hereinafter, embodiments of an amplification device and a radio apparatus disclosed in the present application will be described in detail based on the drawings. It is to be noted that the disclosed technology is not limited by the embodiments. In the embodiments, components having the same function are labeled with the same symbol, and redundant description is omitted.

### First Embodiment

[Configuration Example of Base Station]

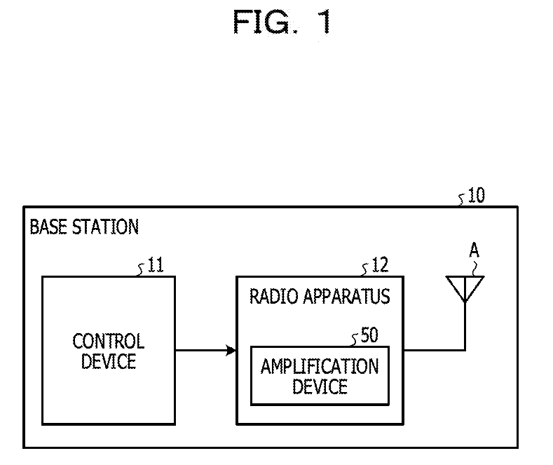

FIG. 1 is a block diagram illustrating an example base station including a radio apparatus in a first embodiment. As illustrated in FIG. 1, a base station 10 has a control device 11 and a radio apparatus 12. The control device 11 and the radio apparatus 12 are coupled by an optical fiber, for instance. Specifically, for instance, in an long term evolution (LTE) system which is standardized by a 3rd generation partnership project (3GPP), a base band unit (BBU) corresponds to the control device 11, and a remote radio head (RRH) corresponds to the radio apparatus 12.

The control device 11 performs predetermined baseband transmission processing such as encoding of transmission data to generate a transmission signal in the baseband, and outputs the generated transmission signal to the radio apparatus 12.

The radio apparatus 12 performs processing such as modulation, up-convert, amplification on a transmission signal inputted from the control device 11, and transmits the signal via an antenna A. The radio apparatus 12 has an amplification device 50, which amplifies the above-mentioned transmission signal.

[Configuration Example of Amplification device]

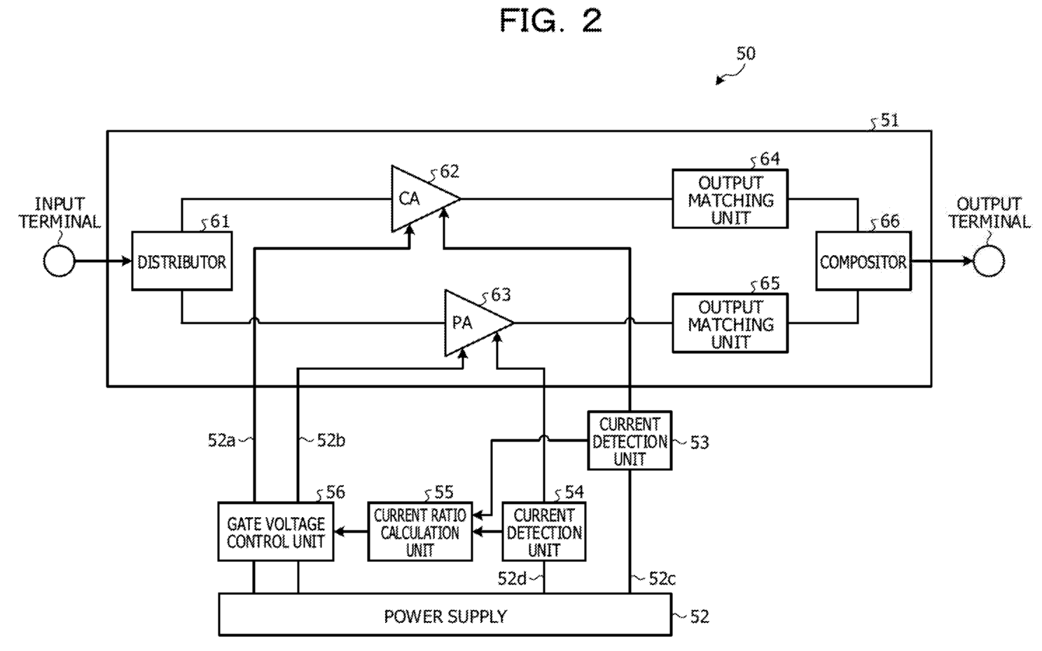

FIG. 2 is a block diagram illustrating an example amplification device in the first embodiment. As illustrated in FIG. 2, the amplification device 50 has an amplification unit 51, a power supply 52, current detection units 53, 54, a current ratio calculation unit 55, and a gate voltage control unit 56.

The amplification unit 51 has a distributor 61, CA 62, PA 63, output matching units 64, 65, and a compositor 66. Specifically, the amplification unit 51 is a Doherty amplification unit (amplification circuit).

When the power value of a transmission signal inputted from an input terminal is less than a predetermined threshold value, the distributor 61 outputs the transmission signal only to the CA 62. On the other hand, when the power value of a transmission signal is greater than or equal to a predetermined threshold value, the distributor 61 outputs the transmission signal to both the CA 62 and the PA 63.

The CA 62 is an amplifier that has linearity when an input power is low, operates with a power supply voltage supplied from the power supply 52, amplifies the power of a transmission signal inputted from the distributor 61, and outputs the amplified signal to the compositor 66 via the output matching unit 64. On the other hand, the PA 63 is an amplifier that is used only when the input power is high, operates with a power supply voltage supplied from the power supply 52, amplifies the power of a transmission signal inputted from the distributor 61, and outputs the amplified signal to the compositor 66 via the output matching unit 65.

The output matching unit 64 adjusts the output-side impedance of the CA 62. The output matching unit 65 adjusts the output-side impedance of the PA 63.

The compositor 66 combines a signal inputted from the CA 62 via the output matching unit 64 with a signal inputted from the PA 63 via the output matching unit 65, and outputs the obtained composite signal as an output signal from an output terminal.

The power supply 52 is a power supply that supplies a power supply voltage to the amplification unit 51. The power supply 52 is coupled to the gate terminal of the CA 62 via a gate bias line 52a, and applies a predetermined gate voltage to the CA 62 using the gate bias line 52a. In addition, the power supply 52 is coupled to the gate terminal of the PA 63 via a gate bias line 52b, and applies a predetermined gate voltage to the PA 63 using the gate bias line 52b. Also, the power supply 52 is coupled to the drain terminal of the CA 62 via a drain bias line 52c, and applies a predetermined drain voltage to the CA 62 using the drain bias line 52c. Also, the power supply 52 is coupled to the drain terminal of the PA 63 via a drain bias line 52d, and applies a predetermined drain voltage to the PA 63 using the drain bias line 52d.

The current detection unit 53 is disposed in the drain bias line 52c to detect a drain current of the CA 62 in the drain bias line 52c, and outputs the detected drain current of the CA 62 to the current ratio calculation unit 55. The drain current of the CA 62 varies due to a temperature change of the CA 62 or a temperature change around the CA 62. Also, the amount of change in the drain current of the CA 62 due to such a temperature change varies with the CA 62. The drain current of the CA 62 increases as the gate voltage applied to the CA 62 is increased, and the drain current of the CA 62 decreases as the gate voltage applied to the CA 62 is decreased. The current detection unit 53 is an example of the first detection unit.

The current detection unit 54 is disposed in the drain bias line 52d to detect a drain current of the PA 63 in the drain bias line 52d, and outputs the detected drain current of the PA 63 to the current ratio calculation unit 55. The drain current of the PA 63 varies due to a temperature change of the PA 63 or a temperature change around the PA 63. Also, the amount of change in the drain current of the PA 63 due to such a temperature change varies with the PA 63. The drain current of the PA 63 increases as the gate voltage applied to the PA 63 is increased, and the drain current of the PA 63 decreases as the gate voltage applied to the PA 63 is decreased. The current detection unit 54 is an example of the second detection unit.

The current ratio calculation unit 55 calculates a current ratio which is a ratio of the drain current of the PA 63 to the drain current of the CA 62 by dividing the drain current of the PA 63 inputted from the current detection unit 54 by the drain current of the CA 62 inputted from the current detection unit 53. Since the amount of change in the drain current of the CA 62 and the PA 63 due to a temperature change varies with the CA 62 and the PA 63, the current ratio calculated by the current ratio calculation unit 55 varies with the CA 62 and the PA 63.

The gate voltage control unit 56 controls a gate voltage applied to the PA 63 using a reference value and a current ratio calculated by the current ratio calculation unit 55. The aforementioned reference value is a predetermined value obtained by pre-measuring a current ratio when distortion of an output signal outputted from the amplification unit 51 is less than or equal to in a predetermined standard value. Specifically, when the current ratio is greater than or equal to a predetermined value, the gate voltage control unit 56 controls the gate voltage applied to the PA 63 until the current ratio falls below the predetermined value. For instance, when the gate voltage applied to the PA 63 is decreased, the drain current of the PA 63, which is the numerator of the current ratio, decreases. Thus, the gate voltage control unit 56 gradually decreases the gate voltage applied to the PA 63 until the current ratio falls below the predetermined value.

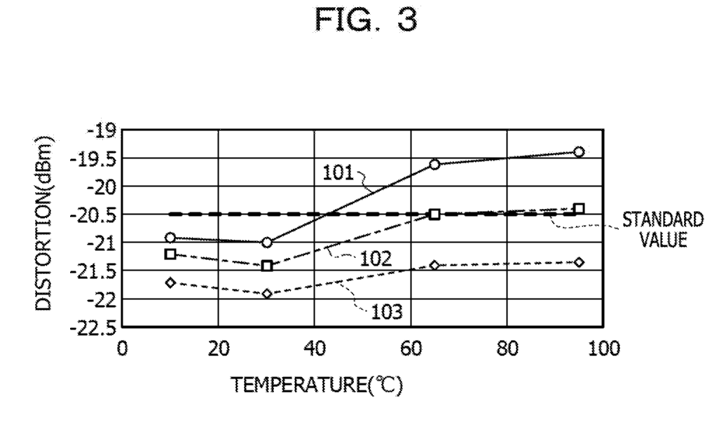

Here, an example of control of the gate voltage by the gate voltage control unit 56 will be described using FIG. 3. FIG. 3 is a graph illustrating an example relationship between current ratio and distortion of an output signal due to change in temperature. In FIG. 3, the horizontal axis indicates the temperature (° C.) in the amplification unit 51, and the vertical axis indicates the distortion (dBm) which occurs in the output signal of the amplification unit 51. In FIG. 3, a graph 101 illustrates a change in distortion of the output signal due to change in temperature when the current ratio is 0.4. In FIG. 3, a graph 102 illustrates a change in distortion of the output signal due to change in temperature when the current ratio is 0.33. In FIG. 3, a graph 103 illustrates a change in distortion of the output signal due to change in temperature when the current ratio is 0.25.

As illustrated in the graphs 101 to 103, distortion which occurs in the output signal of the amplification unit 51 increases as the temperature increases. In addition, an amount of increase in distortion relative to change in temperature increases as the current ratio increases. In the example of FIG. 3, when the current ratio is 0.25, although distortion which occurs in the output signal of the amplification unit 51 increases along with increase of the temperature, the distortion falls within a range of a predetermined standard value (−20.5 dBm) or less. On the other hand, when the current ratio increases to 0.33 or 0.4, distortion which occurs in the output signal of the amplification unit 51 increases along with increase of the temperature, and exceeds the predetermined standard value. In other words, by maintaining the current ratio less than a predetermined value (for instance, 0.3), distortion which occurs in the output signal of the amplification unit 51 falls within a range of a predetermined standard value (for instance, −20.5 dBm) or less.

Thus, when the current ratio is greater than or equal to a predetermined value, the gate voltage control unit 56 controls the gate voltage applied to the PA 63 until the current ratio falls below the predetermined value. In the example of FIG. 3, a case is assumed where the current ratio is 0.4. In this case, since the current ratio is greater than or equal to a predetermined value (0.3), the gate voltage control unit 56 gradually decreases the gate voltage applied to the PA 63 until the current ratio reaches 0.25 which falls below the predetermined value. Thus, as illustrated in the graph 103 of FIG. 3, distortion which occurs in the output signal of the amplification unit 51 falls within a range of a predetermined standard value (−20.5 dBm) or less regardless of the increase in temperature.

[Operation Example of Amplification Device]

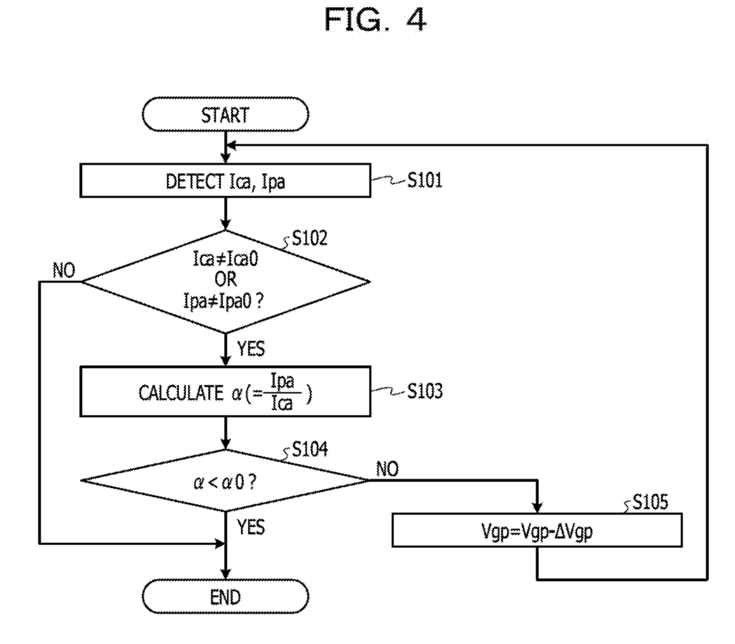

An example of gate voltage control processing in the amplification device 50 having the aforementioned configuration will be described. FIG. 4 is a flowchart illustrating example gate voltage control processing in the first embodiment. The gate voltage control processing illustrated in FIG. 4 is repeatedly performed with a predetermined period (for instance, 30 seconds).

As illustrated in FIG. 4, the current detection unit 53 detects a drain current Ica of the CA 62, and the current detection unit 54 detects a drain current Ipa of the PA 63 (step S101). When the drain current Ica of the CA 62 is the same as the initial value Ica° and the drain current Ipa of the PA 63 is the same as the initial value Ipa0 (No in step S102), the gate voltage control processing is completed. The initial values Ica0, Ipa0 are the values of drain current pre-measured at a reference temperature at the time of factory shipment of the amplification device 50, for instance.

On the other hand, when the drain current Ica of the CA 62 is not the same as the initial value Ica0 or the drain current Ipa of the PA 63 is not the same as the initial value Ipa0 (Yes in step S102), the current ratio calculation unit 55 calculates current ratio α (step S103). Specifically, the current ratio calculation unit 55 calculates the current ratio α by dividing the drain current Ipa of the PA 63 by the drain current Ica of the CA 62.

The gate voltage control unit 56 determines whether or not the current ratio α is less than a predetermined value α0 (step S104). When it is determined by the gate voltage control unit 56 that the current ratio α is less than the predetermined value α0 (Yes in step S104), the gate voltage is not controlled by the gate voltage control unit 56 because the distortion which occurs in the output signal of the amplification unit 51 falls within a range of a predetermined standard value or less.

On the other hand, when the current ratio α is greater than or equal to the predetermined value α0 (No in step S104), the gate voltage Vgp applied to the PA 63 is decreased by a predetermined step voltage ΔVgp (step S105). Thus, the drain current Ipa of the PA 63, which is the numerator of the current ratio α, is reduced by a step current according to the step voltage ΔVgp, and the decreased drain current Ipa of the PA 63 is detected by the current detection unit 54 (step S101). Consequently, the current ratio α calculated by the current ratio calculation unit 55 is decreased (step S103). Subsequently, the gate voltage control unit 56 gradually decreases the gate voltage Vgp applied to the PA 63 by a predetermined step voltage ΔVgp at a time until the current ratio a falls below the predetermined value α0. The step voltage ΔVgp is, for instance, 0.1 V.

When the current ratio α is greater than or equal to a predetermined value α0 like this, the gate voltage Vgp applied to the PA 63 is gradually decreased by a predetermined step voltage ΔVgp at a time until the current ratio α falls below the predetermined value α0. Here, the predetermined value α0 is a measured value of the current ratio α when distortion of the output signal outputted from the amplification unit 51 is less than or equal to in a predetermined standard value. Therefore, when the current ratio α falls below the predetermined value α0, the distortion of the output signal outputted from the amplification unit 51 is less than or equal to in a predetermined standard value, and thus deviation of the gate voltage caused by the individual difference in the CA 62 and PA 63 is reduced. As a consequence, even when the individual difference in the CA 62 and PA 63 is present, the distortion which occurs in the output signal outputted from the amplification unit 51 is reduced.

As described above, in this embodiment, the amplification device 50 has the amplification unit 51, the current detection unit 53, the current detection unit 54, the current ratio calculation unit 55, and the gate voltage control unit 56. The amplification unit 51 is a Doherty amplification unit (amplification circuit) which has the CA 62 and the PA 63. The current detection unit 53 detects a drain current of the CA 62. The current detection unit 54 detects a drain current of the PA 63. The current ratio calculation unit 55 calculates a current ratio which is a ratio of the drain current of the PA 63 to the drain current of the CA 62. The gate voltage control unit 56 controls the gate voltage applied to the PA 63 using the reference value and the current ratio calculated by the current ratio calculation unit 55. The aforementioned reference value is a predetermined value obtained by pre-measuring a current ratio when distortion of an output signal outputted from the amplification unit 51 is less than or equal to in a predetermined standard value. For instance, when the current ratio is greater than or equal to a predetermined value, the gate voltage control unit 56 decreases the gate voltage applied to the PA 63 until the current ratio falls below the predetermined value.

With this configuration of the amplification device 50, when the current ratio falls below a predetermined value, the distortion of the output signal outputted from the amplification unit 51 is less than or equal to in a predetermined standard value, and thus deviation of the gate voltage caused by the individual difference in the CA 62 and PA 63 is reduced. As a consequence, even when the individual difference in the CA 62 and PA 63 is present, the distortion which occurs in the output signal outputted from the Doherty circuit is reduced.

In the amplification device 50, the current detection unit 53 detects a drain current of the CA 62 in the drain bias line 52c coupled to the drain terminal of the CA 62. The current detection unit 54 then detects a drain current of the PA 63 in the drain bias line 52d coupled to the drain terminal of the PA 63.

With this configuration of the amplification device 50, the drain current of the CA 62 and the drain current of the PA 63 are detected with high accuracy, and thus the gate voltage is controlled with high accuracy using the current ratio, and as a consequence, the occurrence of distortion in the Doherty circuit can be further reduced.

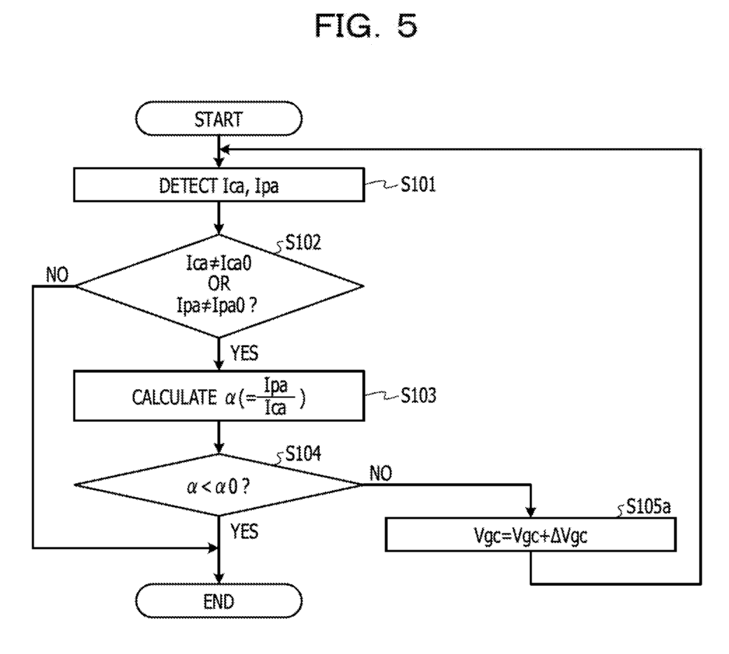

It is to be noted that in the above description, when the current ratio is greater than or equal to a predetermined value, the gate voltage applied to the PA 63 is decreased until the current ratio falls below the predetermined value. However, the gate voltage applied to the CA 62 may be increased until the current ratio falls below the predetermined value. FIG. 5 is a flowchart illustrating another example gate voltage control processing in the first embodiment. It is to be noted that in FIG. 5, the same portion as in FIG. 4 is labeled with the same symbol, and detailed description thereof is omitted. The gate voltage control processing illustrated in FIG. 5 is repeatedly performed with a predetermined period (for instance, 30 seconds).

As illustrated in FIG. 5, the current detection unit 53 detects a drain current Ica of the CA 62, and the current detection unit 54 detects a drain current Ipa of the PA 63 (step S101). When the drain current Ica of the CA 62 is the same as the initial value Ica0 and the drain current Ipa of the PA 63 is the same as the initial value Ipa0 (No in step S102), the gate voltage control processing is completed. The initial values Ica0, Ipa0 are the values of drain current pre-measured at a reference temperature at the time of factory shipment of the amplification device 50, for instance.

On the other hand, when the drain current Ica of the CA 62 is not the same as the initial value Ica0 or the drain current Ipa of the PA 63 is not the same as the initial value Ipa0 (Yes in step S102), the current ratio calculation unit 55 calculates current ratio α (step S103). Specifically, the current ratio calculation unit 55 calculates the current ratio α by dividing the drain current Ipa of the PA 63 by the drain current Ica of the CA 62.

The gate voltage control unit 56 determines whether or not the current ratio α is less than a predetermined value α0 (step S104). When it is determined by the gate voltage control unit 56 that the current ratio α is less than the predetermined value α0 (Yes in step S104), the gate voltage is not controlled by the gate voltage control unit 56 because the distortion which occurs in the output signal of the amplification unit 51 falls within a range of a predetermined standard value or less.

On the other hand, when the current ratio α is greater than or equal to the predetermined value α0 (No in step S104), the gate voltage Vgc applied to the CA 62 is increased by a predetermined step voltage ΔVgc (step S105a). Thus, the drain current Ica of the CA 62, which is the denominator of the current ratio α , is increased by a step current according to the step voltage ΔVgc, and the increased drain current Ica of the CA 62 is detected by the current detection unit 53 (step S101). Consequently, the current ratio α calculated by the current ratio calculation unit 55 is decreased (step S103). Subsequently, the gate voltage control unit 56 gradually increases the gate voltage Vgc applied to the CA 62 by a predetermined step voltage ΔVgc at a time until the current ratio a falls below the predetermined value α0. The step voltage ΔVgc is, for instance, 0.1 V.

When the current ratio α is greater than or equal to a predetermined value α0 like this, the gate voltage Vgc applied to the CA 62 is gradually increased by a predetermined step voltage ΔVgc at a time until the current ratio α falls below the predetermined value α0. Here, the predetermined value α0 is a measured value of the current ratio α when distortion of the output signal outputted from the amplification unit 51 is less than or equal to in a predetermined standard value. Therefore, when the current ratio α falls below the predetermined value α0, the distortion of the output signal outputted from the amplification unit 51 is less than or equal to in a predetermined standard value, and thus deviation of the gate voltage caused by the individual difference in the CA 62 and PA 63 is reduced. As a consequence, even when the individual difference in the CA 62 and PA 63 is present, the distortion which occurs in the output signal outputted from the amplification unit 51 is reduced.

It is to be noted that although the gate voltage applied to one of the CA 62 and the PA 63 is controlled by the above description, the gate voltage applied to both of the CA 62 and the PA 63 may be controlled.

### Second Embodiment

When a current detection unit is directly disposed in a line coupled to the drain terminal of each of the CA 62 and the PA 63, the power may be lost in the line. Thus, in a second embodiment, the temperature of the line coupled to the drain terminal of each of the CA 62 and the PA 63 is detected in a non-contact manner, and the temperature is converted into a drain current of each of the CA 62 and the PA 63. It is to be noted that the basic configuration of a base station in the second embodiment is the same as the configuration of the base station 10 in the first embodiment.

[Configuration Example of Amplification Device]

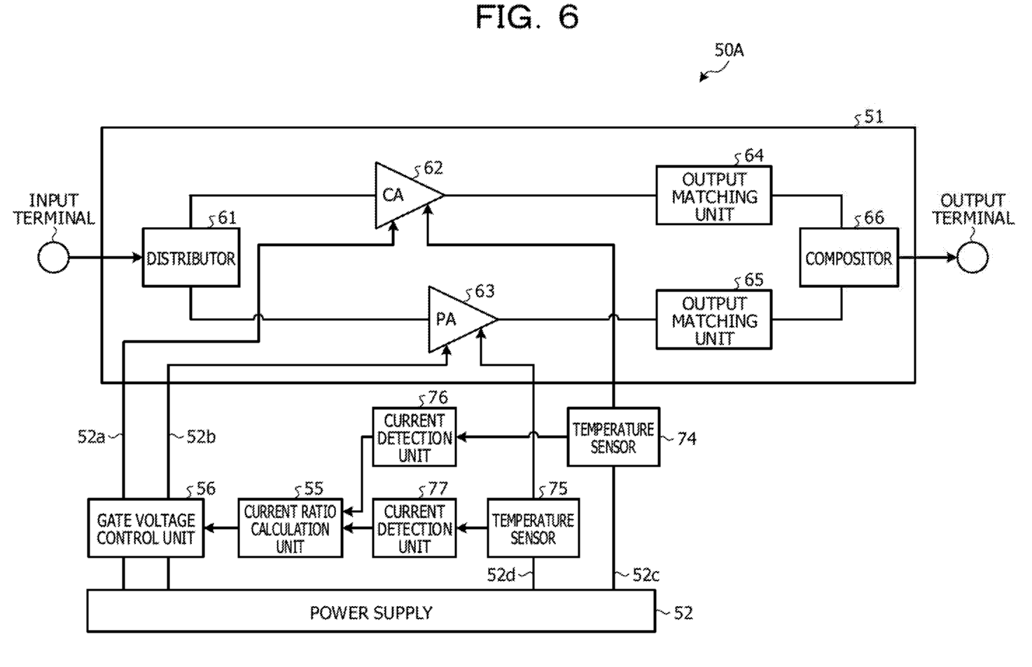

FIG. 6 is a block diagram illustrating an example amplification device in the second embodiment. In FIG. 6, the same portion as in FIG. 2 is labeled with the same symbol, and a description thereof is omitted. As illustrated in FIG. 6, an amplification device 50A has temperature sensors 74, 75 and current detection units 76, 77.

The temperature sensor 74 measures the temperature of the drain bias line 52c in a non-contact manner, and outputs the measured temperature of the drain bias line 52c to the current detection unit 76. The temperature sensor 74 is an example of the first measurement unit.

The temperature sensor 75 measures the temperature of the drain bias line 52d in a non-contact manner, and outputs the measured temperature of the drain bias line 52d to the current detection unit 77. The temperature sensor 75 is an example of the second measurement unit.

The current detection unit 76 converts the temperature of the drain bias line 52c inputted from the temperature sensor 74 into a drain current of the CA 62, and outputs the converted drain current of the CA 62 to the current ratio calculation unit 55.

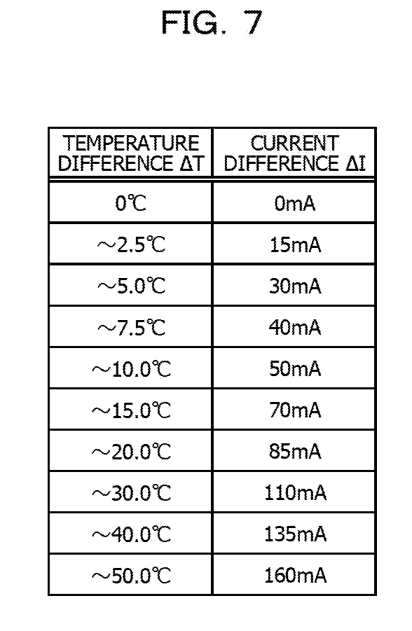

FIG. 7 is a table illustrating an example conversion table in which a range of temperature difference and a current difference are associated with each other. For instance, the current detection unit 76 converts the temperature of the drain bias line 52c inputted from the temperature sensor 74 into a drain current of the CA 62, using the conversion table illustrated in FIG. 7. Specifically, the current detection unit 76 calculates a difference in temperature by subtracting the initial value of the temperature of the drain bias line 52c from the temperature of the drain bias line 52c inputted from the temperature sensor 74. Here, it is assumed the difference in temperature calculated by the current detection unit 76 is “6.0° C. In this case, the current detection unit 76 uses the conversion table to obtain a current difference “40 mA” corresponding to a range of “to 7.5° C. ” to which difference in temperature “6.0° C. ” belongs. The current detection unit 76 then calculates a drain current of the CA 62 by adding the obtained current difference “40 mA” to the initial value of the drain current of the CA 62.

The current detection unit 77 converts the temperature of the drain bias line 52d inputted from the temperature sensor 75 into a drain current of the PA 63, and outputs the converted drain current of the PA 63 to the current ratio calculation unit 55. For instance, the current detection unit 77 uses the aforementioned conversion table illustrated in FIG. 7 to convert the temperature of the drain bias line 52d into a drain current of the PA 63 by the same technique as used by the current detection unit 76.

[Operation Example of Amplification Device]

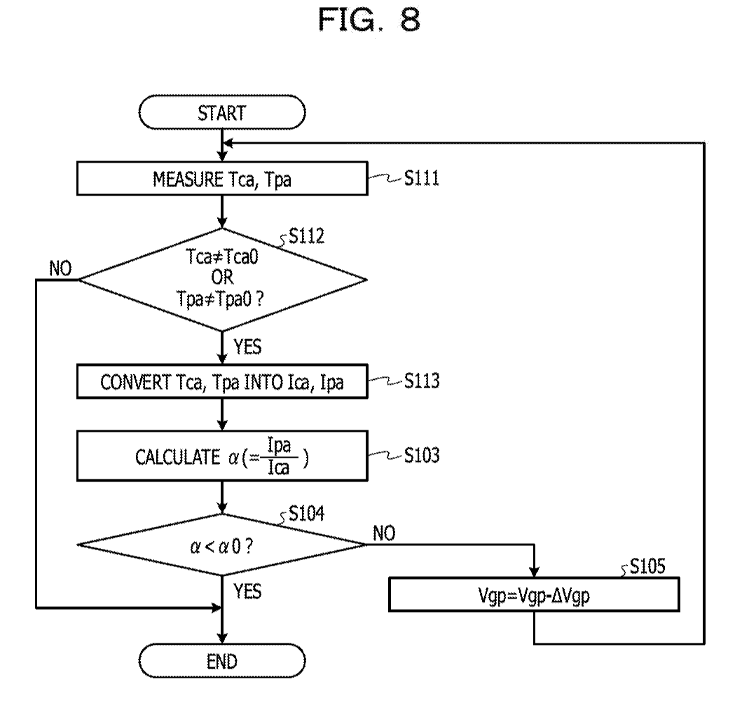

An example of gate voltage control processing in the amplification device 50A having the aforementioned configuration will be described. FIG. 8 is a flowchart illustrating example gate voltage control processing in the second embodiment. It is to be noted that in FIG. 8, the same portion as in FIG. 4 is labeled with the same symbol, and detailed description thereof is omitted. The gate voltage control processing illustrated in FIG. 8 is repeatedly performed with a predetermined period (for instance, 30 seconds).

As illustrated in FIG. 8, the temperature sensor 74 measures the temperature Tca of the drain bias line 52c in a non-contact manner, and the temperature sensor 75 measures the temperature Tpa of the drain bias line 52d in a non-contact manner (step S111). When the temperature Tca of the drain bias line 52c is the same as the initial value Tca0 and the temperature Tpa of the drain bias line 52d is the same as the initial value Tpa0 (No in step S112), the gate voltage control processing is completed. The initial values Tca0, Tpa0 are the values of temperature pre-measured at a reference temperature at the time of factory shipment of the amplification device 50A, for instance.

On the other hand, when the temperature Tca of the drain bias line 52c is not the same as the initial value Tca0 or the temperature Tpa of the drain bias line 52d is not the same as the initial value Tpa0 (Yes in step S112), the current detection unit 76 and the current detection unit 77 perform the following processing. That is, the current detection unit 76 converts the temperature Tca of the drain bias line 52c into the drain current Ica of the CA 62, and the current detection unit 77 converts the temperature Tpa of the drain bias line 52d into the drain current Ipa of the PA 63 (step S113). For instance, the current detection unit 76 and the current detection unit 77 perform conversion from the temperature to a drain current using the conversion table illustrated in FIG. 7.

The current ratio calculation unit 55 then calculates the current ratio α (step S103). Specifically, the current ratio calculation unit 55 calculates the current ratio α by dividing the drain current Ipa of the PA 63 by the drain current Ica of the CA 62.

The gate voltage control unit 56 determines whether or not current ratio α is less than the predetermined value α0 (step S104). When it is determined by the gate voltage control unit 56 that the current ratio α is less than the predetermined value α0 (Yes in step S104), the gate voltage is not controlled by the gate voltage control unit 56 because the distortion which occurs in the output signal of the amplification unit 51 falls within a range of a predetermined standard value or less.

On the other hand, when the current ratio α is greater than or equal to the predetermined value α0 (No in step S104), the gate voltage Vgp applied to the PA 63 is decreased by a predetermined step voltage ΔVgp (step S105). Thus, the drain current Ipa of the PA 63, which is the numerator of the current ratio α , is reduced by a step current according to the step voltage ΔVgp, and the decreased drain current Ipa of the PA 63 is obtained by the conversion of the current detection unit 77 (step S113). Consequently, the current ratio α calculated by the current ratio calculation unit 55 is decreased (step S103). Subsequently, the gate voltage control unit 56 gradually decreases the gate voltage Vgp applied to the PA 63 by a predetermined step voltage ΔVgp at a time until the current ratio α falls below the predetermined value α0. The step voltage ΔVgp is, for instance, 0.1 V.

When the current ratio α is greater than or equal to a predetermined value α0 like this, the gate voltage Vgp applied to the PA 63 is gradually decreased by a predetermined step voltage ΔVgp at a time until the current ratio α falls below the predetermined value α0. Here, the predetermined value α0 is a measured value of the current ratio α when distortion of the output signal outputted from the amplification unit 51 is less than or equal to in a predetermined standard value. Therefore, when the current ratio α falls below the predetermined value α0, the distortion of the output signal outputted from the amplification unit 51 is less than or equal to in a predetermined standard value, and thus deviation of the gate voltage caused by the individual difference in the CA 62 and PA 63 is reduced. As a consequence, even when the individual difference in the CA 62 and PA 63 is present, the distortion which occurs in the output signal outputted from the amplification unit 51 is reduced.

As described above, in this embodiment, the amplification device 50A has the temperature sensor 74 and the temperature sensor 75. The temperature sensor 74 measures the temperature of the drain bias line 52c coupled to the drain terminal of the CA 62 in a non-contact manner. The temperature sensor 75 measures the temperature of the drain bias line 52d coupled to the drain terminal of the PA 63 in a non-contact manner. The current detection unit 76 then converts the temperature of the drain bias line 52c measured by the temperature sensor 74 into the temperature of the CA 62. Also, the current detection unit 77 converts the temperature of the drain bias line 52d measured by the temperature sensor 75 into the temperature of the PA 63.

The configuration of the amplification device 50A allows power loss to be reduced in the line coupled to the drain terminal of each of the CA 62 and the PA 63. Consequently, the occurrence of distortion in the Doherty circuit can be further reduced and power consumption can be reduced.

### Other Embodiments

In the first and second embodiments, the current ratio calculation unit 55 and the gate voltage control unit 56 are implemented, for instance, by a field programmable gate array (FPGA), a large scale integrated circuit (LSI), or a processor as hardware. In addition, the current detection unit 76 and the current detection unit 77 are implemented, for instance, by an FPGA, an LSI, or a processor as hardware.

Although the radio apparatus 12 is coupled to the control device 11 in the description of the first and second embodiments, the control device 11 and the radio apparatus 12 do not have to be provided separately. For instance, the radio apparatus 12 may perform predetermined baseband transmission processing such as encoding of transmission data to generate a transmission signal in the baseband.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An amplification device comprising:
a first amplifier configured to amplify an input signal in accordance with a first gate voltage; and
a second amplifier configured to amplify the input signal in accordance with a second gate voltage,
wherein at least one of the first gate voltage and the second gate voltage are controlled on the basis of a current ratio of a first drain current of the first amplifier to a second drain current of the second amplifier.

2. The amplification device according to claim 1, further comprising:
a memory; and
a processor coupled to the memory and configured to:
detect the first drain current;
detect the second drain current;
calculate the current ratio; and
control at least one of the first gate voltage and the second gate voltage based on the current ratio.

3. The amplification device according to claim 2, the processor further configured to:
control at least one of the first gate voltage and the second gate voltage based on the current ratio and a reference value stored in the memory.

4. The amplification device according to claim 3,
wherein the reference value is a predetermined value which is a measured value of the current ratio when a distortion of a signal outputted from the first and second amplifiers are less than or equal to a predetermined standard value, and
when the current ratio is greater than or equal to the predetermined value, the processor controls the first gate voltage and the second gate voltage until the current ratio falls below the predetermined value.

5. The amplification device according to claim 2, the processor further configured to:
detect the first drain current in a first line coupled to a first drain terminal of the first amplifier; and
detect the second drain current in a second line coupled to a second drain terminal of the second amplifier.

6. The amplification device according to claim 2, the processor further configured to:
measure a first temperature of a first line coupled to a first drain terminal of the first amplifier, in a non-contact manner;
measure a second temperature of a second line coupled to a second drain terminal of the second amplifier, in a non-contact manner;
convert the first temperature into the second drain current; and
convert the second temperature into the second drain current.
